(19) United States
(12) Patent Application Publication
(10) Pub. No.: US 2026/0229801 A1
(43) Pub. Date: Aug. 6, 2026

(54) SOLDER AREA FORMED TO CAPTURE TWO WIRES

(71) Applicant: KOLLMORGEN CORPORATION, Radford, VA (US)

(72) Inventor: Martin DOLEŽAL, Breclav (CZ)

(73) Assignee: KOLLMORGEN CORPORATION, Radford, VA (US)

(21) Appl. No.: 19/467,142

(22) Filed: Feb. 2, 2026

Related U.S. Application Data
(60) Provisional application No. 63/751,916, filed on Jan. 31, 2025.

(51) Int. Cl. H01R 12/53; H01R 4/02; H05K 1/11

(52) U.S. Cl. CPC H01R 12/53; H01R 4/027; H05K 1/111; H01R 2201/10

(57) ABSTRACT

A printed circuit board assembly is provided for electrically connecting a bifilar winding to a single solder pad. The assembly includes a solder pad and a wire capture area formed in the printed circuit board adjacent the solder pad. The wire capture area defines a guided wire path configured to receive two wires of a bifilar winding and mechanically constrain the wires relative to one another and relative to the solder pad. In various embodiments, the guided wire path includes a uniform channel and a wedge area that cooperate to laterally compress and wedge the wires together, converting elastic restoring forces of the wires into contact forces that maintain exposed conductor portions of both wires in contact with the solder pad during soldering.

### CROSS-REFERENCE TO RELATED APPLICATIONS

This application claims the benefit of U.S. Provisional Patent Application No. 63/751,916 , filed Jan. 31, 2025, and titled “SOLDER AREA FORMED TO CAPTURE TWO WIRES,” the entire disclosure of which is incorporated herein by reference.

### FIELD OF THE DISCLOSURE

The present disclosure relates generally to electromagnetic motors and, more particularly, to wound armature stators and electrical interconnection structures and methods for connecting armature coil windings in electromagnetic motors.

### BACKGROUND

Electromagnetic motors, including brushless rotary motors and linear motors, rely on interaction between electromagnetic fields generated in a wound armature and permanent magnets carried by a rotor or magnet assembly. In brushless rotary motors, a rotor having permanent magnets arranged on outwardly extending poles is surrounded by a stationary armature assembly that is typically circular and ring-shaped. The rotor is commonly coupled to a shaft to provide rotational torque. Linear motors operate on similar principles but generate linear motion rather than rotational motion.

A typical prior art armature is formed from a plurality of stacked and laminated layers that define a central hub and a plurality of radially extending teeth separated by open slots. The armature is wound by placing coils of conductive wire within the slots. When electrical current flows through the coils, electromagnetic fields are induced in the teeth, which interact with the permanent magnets of the rotor to produce attracting and repulsing forces that cause motion. Controlled commutation of current through the coils enables synchronous operation of the motor.

After winding, the armature requires electrical connections between individual coils and between the coils and external lead wires in order to form motor phases and enable commutation. These interconnections must be reliable while also being manufacturable at low cost. However, existing approaches to forming these electrical connections present several challenges, particularly in motors using high copper slot fill and multi-conductor winding techniques.

Armature windings may be formed using a variety of manufacturing methods, including manual turn by turn winding directly on the armature teeth, insertion of prewound coils into the armature slots, automated needle winding processes, and segmented stator constructions. Needle winding techniques, such as those described in U.S. Pat. No. 7,135,799, enable automated continuous winding but still require subsequent connection and disconnection operations to complete assembly. Segmented stator designs, such as those described in U.S. Pat. No. 10,468,930, allow for high density windings using individual stator segments, but require reassembly of the segments into a complete armature stator and introduce additional interconnection complexity.

Printed circuit boards are commonly used to implement the interconnection system for wound armatures. The printed circuit board is used to electrically connect individual coil windings together to form motor phases and to connect those phases to motor lead wires. In many designs, the printed circuit board incorporates connection terminals, such as insulation displacement connection terminals, or provides solder pads to which the ends of the coil winding wires are attached.

Motor performance is strongly influenced by the amount of copper present in the armature slots. High slot fill is desirable because it reduces electrical resistance, improves thermal conductivity, and increases efficiency and power output. Armature windings are therefore commonly formed using unifilar winding, in which a single conductor is wound for each turn, with the conductor size selected to maximize slot fill for the required number of turns.

In motors requiring a reduced number of turns, larger conductor sizes are often needed to maintain high copper slot fill. However, as conductor size increases, the stiffness of the wire and the winding tension required make winding more difficult. To address these challenges, multiple conductors are often wound together for each turn. When two conductors are wound in hand for each turn, the winding is referred to as bifilar winding.

Bifilar windings are particularly common in motors having large diameters or long axial stack lengths, as such motors typically require fewer turns to reduce back electromotive force voltage and winding impedance for higher speed operation at a given rated voltage. Bifilar windings are also used in low voltage motor applications, including smaller motors, where a low number of turns is required. While bifilar winding improves manufacturability and electrical performance in these applications, it introduces additional challenges for electrical interconnection.

In prior art armature assemblies employing bifilar windings, printed circuit boards are used to provide coil to coil connections and to connect input power lines to selected coils for commutation. One commonly used approach employs insulation displacement connection terminals to electrically connect the bifilar winding conductors to the printed circuit board.

However, in bifilar applications, insulation displacement terminals may fail to adequately cut through the insulation of both conductors. Insufficient cutting can result in unreliable electrical connections and can cause mechanical interference or scraping of the armature assembly during manufacture or operation. These issues may arise from terminal design or from the configuration of the terminal pocket in the insulating structure, which may not be optimized for both unifilar and bifilar windings.

An alternative approach is to eliminate insulation displacement terminals and directly solder the armature coil wires to conductive areas of the printed circuit board. While direct soldering can improve electrical reliability, soldering each conductor of a bifilar winding separately would require a separate solder pad and solder joint for each wire. This increases printed circuit board area, material cost, and assembly time. Although soldering both conductors of a bifilar winding simultaneously to a single solder pad would be the most cost effective and efficient solution, existing designs lack a reliable mechanism for retaining and positioning both conductors during the soldering process.

### SUMMARY

Accordingly, there exists a need for improved armature interconnection techniques that reliably accommodate bifilar windings, reduce manufacturing complexity and cost, and maintain high electrical and mechanical performance of the motor.

The subject technology addresses the technical challenge of reliably forming an electrical connection between a bifilar armature winding and a single solder pad of a printed circuit board. In applications where two conductors are wound in hand for each turn and are intended to be joined at a common solder pad, it is necessary to ensure that both conductors are simultaneously positioned and retained within the solder pad to enable formation of a consistent and electrically robust solder joint.

Armature winding conductors possess inherent elastic characteristics arising from their material properties and from deformation imparted during the winding and routing processes. These elastic characteristics generate restoring forces that tend to bias the conductors away from a desired soldering position once external positioning forces are removed. In bifilar windings, the presence of two adjacent conductors introduces compounded and potentially nonuniform restoring forces that increase the likelihood of conductor displacement during soldering.

The subject technology overcomes these challenges by providing a printed circuit board interface that mechanically restrains both conductors of a bifilar winding relative to a single solder pad. By counteracting the elastic restoring forces of the conductors, the interface maintains both conductors in stable engagement with the solder pad during solder application and solidification, thereby enabling efficient soldering to a single pad while ensuring reliable electrical and mechanical connection.

In various embodiments, the printed circuit board interface achieves the foregoing retention and positioning of both conductors without requiring insulation displacement connection terminals, separate terminals for each conductor, or external fixturing to hold the conductors on the solder pad during solder application. Instead, the wire capture area formed in the printed circuit board itself provides mechanical constraint that stabilizes the conductors relative to the single solder pad, such that both exposed conductor portions remain in solderable engagement with the pad as solder is applied and solidifies, thereby reducing printed circuit board area and assembly complexity while improving connection consistency.

The present disclosure relates to printed circuit board assemblies used to electrically connect bifilar windings to printed circuit board circuitry, and more particularly to printed circuit board structures configured to receive, position, and retain two or more winding wires on a single solder pad during soldering. It is envisioned that two pairs of bifilar wires may be received, positioned and retained for soldering by a properly sized and shaped opening.

In one aspect, a printed circuit board assembly includes a printed circuit board having a surface that defines a solder pad, and a wire capture area formed in the printed circuit board adjacent the solder pad. The wire capture area is configured to receive two wires of a bifilar winding and to mechanically wedge the two wires together such that both wires are maintained in contact with the solder pad for soldering. By mechanically wedging the two wires, the wire capture area stabilizes the wires relative to one another and relative to the solder pad during solder application without external restraint.

In some embodiments, the wire capture area includes a posterior wedge portion configured to laterally compress the two wires toward one another when the two wires are simultaneously received in the wire capture area. The posterior wedge portion may be positioned relative to the solder pad such that lateral compression of the two wires also urges exposed conductor portions of both wires into contact with the solder pad.

In further embodiments, the wire capture area includes a uniform channel and a posterior wedge portion positioned at a terminal end of the uniform channel. The uniform channel is configured to receive the two wires in a side-by-side orientation and to constrain relative vertical and lateral movement of the two wires prior to entry into the posterior wedge portion. In some configurations, the uniform channel has a width greater than a diameter of each wire individually and smaller than a sum of the diameters of the two wires, thereby preventing one wire from passing above or below the other wire. An opening leading into the uniform channel may permit insertion of the two wires without precise lateral alignment while transitioning the wires into the constrained side-by-side orientation.

In certain embodiments, the posterior wedge portion includes curved boundary surfaces that establish multiple simultaneous contact regions between the two wires and the printed circuit board when the wires are seated. The curved boundary surfaces may be arranged asymmetrically such that one wire is urged into a laterally offset position relative to the other wire during seating. In such arrangements, elastic restoring forces of the two wires may increase a wedging force between the two wires after insertion into the posterior wedge portion.

In another aspect, a printed circuit board assembly includes a printed circuit board defining a solder pad configured as a single electrical node and a slot formed in the printed circuit board adjacent the solder pad. The slot includes a uniform channel and a posterior wedge portion. The uniform channel is configured to receive two wires of a bifilar winding in a side-by-side orientation, and the posterior wedge portion is configured to laterally compress the two wires toward one another and toward the solder pad. In this configuration, elastic restoring forces of the two wires contribute to retaining the two wires in contact with the solder pad.

In some embodiments, the uniform channel restricts relative vertical displacement of the two wires prior to entry into the posterior wedge portion and prevents one wire from passing above or below the other wire. The posterior wedge portion may include asymmetrically arranged boundary surfaces configured to seat the two wires at laterally offset positions and to establish multiple simultaneous contact regions including at least one wire-to-wire contact region and at least one wire-to-slot contact region.

In a further aspect, a printed circuit board assembly includes a printed circuit board having a solder pad and a wire capture area formed in the printed circuit board adjacent the solder pad. The wire capture area is configured to receive two wires of a bifilar winding and to mechanically constrain the two wires such that placement of the two wires within the wire capture area urges exposed conductor portions of both wires into contact with the solder pad during soldering.

In some embodiments, the wire capture area includes a uniform channel configured to guide the two wires into a defined relative orientation prior to engagement with the solder pad and a posterior wedge portion configured to laterally compress the two wires toward one another as the wires are advanced toward the solder pad. The solder pad may extend beneath at least a portion of the wire capture area such that mechanical constraint of the two wires generates a downward force component urging the exposed conductor portions toward the solder pad. In certain embodiments, the wire capture area maintains the two wires in contact with the solder pad without external fixturing during solder application and converts elastic restoring forces of the two wires into increased contact force between the exposed conductor portions and the solder pad.

### BRIEF DESCRIPTION OF THE DRAWINGS

Various aspects of the present disclosure are discussed herein with reference to the accompanying Figures. It will be appreciated that for simplicity and clarity of illustration, elements shown in the drawings have not necessarily been drawn accurately or to scale. For example, the dimensions of some of the elements can be exaggerated relative to other elements for clarity or several physical components can be included in one functional block or element. Further, where considered appropriate, reference numerals can be repeated among the drawings to indicate corresponding or analogous elements. For purposes of clarity, however, not every component can be labeled in every drawing. The Figures are provided for the purposes of illustration and explanation and are not intended as a definition of the limits of the disclosure.

FIG. 1 is a perspective view of a prior art armature assembly including an armature core with bifilar windings and a printed circuit board used for electrical interconnection.

FIG. 2 is a view illustrating a prior art printed circuit board configured to interconnect armature coil windings to form motor phases.

FIG. 3 is a view illustrating a prior art printed circuit board configured to connect armature coil windings or motor phases to external lead wires.

FIG. 4 is an enlarged view of a prior art connection interface between armature winding conductors and a printed circuit board connection terminal.

FIG. 5 is a partial cross-sectional view of a printed circuit board assembly illustrating slots formed in the printed circuit board for routing individual winding wires through the printed circuit board toward a solder pad.

FIG. 6 illustrates various solder pads and adjacent slot or capture geometries, shown in somewhat schematic depictions and corresponding printed circuit board implementations, including a configuration having a wire-receiving terminal region positioned adjacent a solder pad in accordance with the subject technology.

FIG. 7A is a somewhat schematic top view of a printed circuit board assembly illustrating a wire capture area formed adjacent a solder pad and including an opening, a uniform channel, and a posterior wedge portion.

FIG. 7B is a perspective view of a printed circuit board assembly illustrating a physical implementation of the wire capture area of FIG. 7A prior to application of solder.

FIG. 8 is a perspective view of the printed circuit board assembly of FIG. 7B illustrating a condition following solder application, in which two wires are retained by the wire capture area and electrically connected to the solder pad.

FIG. 9 is a view illustrating potential positions of two wires as the wires are in the wire capture area and positioned on the solder pad for soldering.

FIG. 10 is an enlarged view of the posterior wedge portion illustrating curved boundary surfaces configured to establish multiple contact regions for receiving and wedging two wires.

FIG. 11 is a view of a printed circuit board assembly illustrating an alternative solder pad geometry having an oval shaped wire capture area.

FIG. 12 is a view of a printed circuit board assembly illustrating a further alternative solder pad geometry including a segmented or stepped perimeter wire capture area.

### DETAILED DESCRIPTION

The subject technology overcomes many of the prior art problems associated with electrically connecting bifilar armature windings to printed circuit board interconnection structures. The advantages, and other features of the technology disclosed herein, will become more readily apparent to those having ordinary skill in the art from the following detailed description of certain exemplary embodiments taken in combination with the drawings and wherein like reference numerals identify similar structural elements. It should be noted that directional indications such as vertical, horizontal, upward, downward, right, left and the like, are used with respect to the figures and not meant in a limiting manner.

In particular, the subject technology generally concerns a printed circuit board assembly provided with an integrated wire capture structure configured to mechanically manage two conductors of a bifilar winding during soldering to a single solder pad. The wire capture structure defines a guided wire path that receives the two wires and progressively constrains their movement as they advance toward the solder pad. In particular, the guided path transitions from an entrance region that permits relatively loose insertion into a constrained channel that arranges the wires in a controlled side-by-side relationship, limiting relative vertical and lateral movement and positioning exposed conductor portions of both wires on the solder pad prior to solder application.

The guided wire path further includes a wedging region adjacent the solder pad that mechanically engages the wires at multiple locations. In various embodiments, the wedging geometry is asymmetric, causing one wire to seat more deeply while urging the second wire laterally toward the first wire and the solder pad. As the wires are bent and seated within this region, elastic restoring forces inherent to the wires are redirected into contact forces that increase pressure at wire-to-wire and wire-to-board interfaces. In this way, the structure converts wire elasticity into a stabilizing wedging action that retains both wires in reliable solderable engagement with the solder pad throughout solder application and solidification, without reliance on external fixturing.

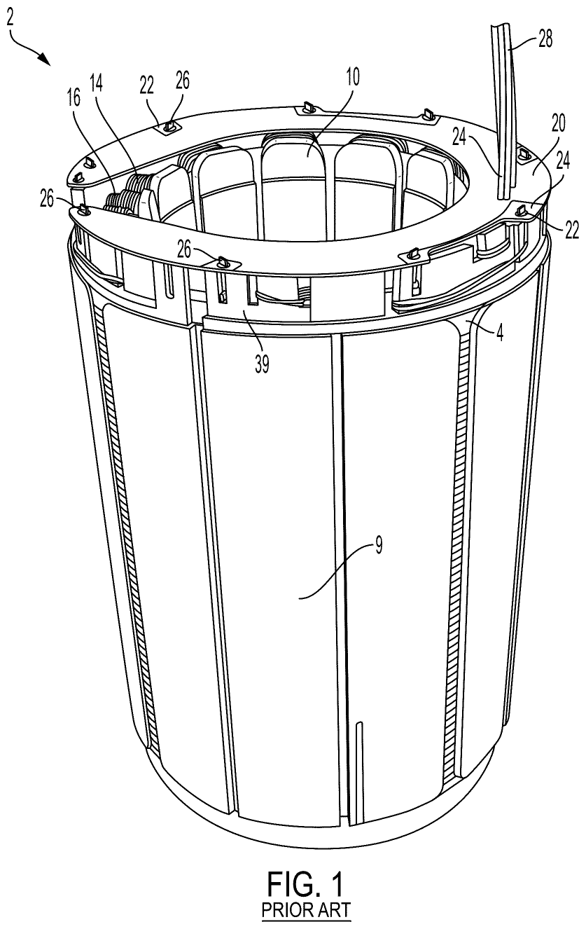

Before describing the present wire capture structures in detail, it is useful to consider representative prior art armature interconnection arrangements. FIGS. 1-4 illustrate conventional approaches used to electrically connect armature coil windings to printed circuit boards, including terminal-based and insulation displacement configurations commonly employed in bifilar winding applications. As discussed below, while these arrangements can provide electrical continuity, they do not reliably control the positioning or retention of multiple conductors at a single soldering location and give rise to the mechanical and manufacturing limitations addressed by the subject technology.

Referring now to FIG. 1, a prior art armature assembly 2 for an electromagnetic motor is illustrated. The armature assembly 2 includes an armature core 4 defining a central hub portion 8 and a plurality of radially extending teeth circumferentially spaced about the central hub portion 8.

The armature core 4 is configured to receive armature coil windings 14 wound around the teeth 10. In the illustrated configuration, the armature coil windings 14 are arranged as bifilar windings 16, such that each bifilar winding 16 includes two conductor wires wound together around a respective tooth.

The armature assembly 2 further includes a printed circuit board 20 positioned adjacent the armature core 4. The printed circuit board 20 is configured to provide electrical interconnections between individual armature coil windings 14 and to connect selected armature coil windings 14 to external lead wires 28 for motor commutation. Electrical connection between the armature coil windings 14 and the printed circuit board 20 is accomplished through connection terminals 22 mounted on the printed circuit board 20. The connection terminals 22 are configured to receive end portions 26 of the armature coil windings 14 and to establish electrical continuity between the armature coil windings 14 and conductive portions 24 of the printed circuit board 20.

As shown, the printed circuit board 20 is arranged circumferentially around the armature core 4, with the connection terminals 22 positioned to align with corresponding coil end portions 26.

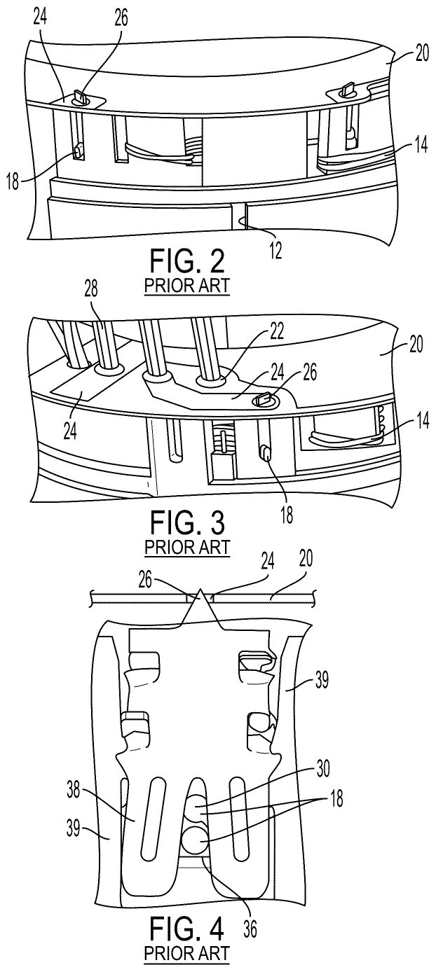

Referring now to FIGS. 2 and 3, the printed circuit board 20 is shown in greater detail in relation to the electrical connection of the armature coil windings 14 and the external lead wires 28. End portions 26 of the armature coil windings 14 extend toward the connection terminal 26. The printed circuit board 20 includes a plurality of connection terminals 22 mounted thereon and positioned to receive the end portions 26 of the armature coil windings 14.

The connection terminals 22 are configured to establish electrical communication between the armature coil windings 14 and conductive traces 24 formed on the printed circuit board 20. FIG. 2 illustrates the manner in which individual armature coil windings 14 are electrically interconnected via the printed circuit board 20 to form motor phases. FIG. 3 illustrates the manner in which selected armature coil windings 14 or motor phases are electrically connected to external lead wires 28 through the printed circuit board 20 for supplying electrical power and enabling commutation. In each configuration, the printed circuit board 20 functions as an interconnection structure that provides electrical continuity between the armature coil windings 14 and associated circuitry or the external lead wires 28.

Referring now to FIG. 4, a prior art armature interconnection terminal 38 held in place by an end insulator 39 is illustrated in greater detail. FIG. 4 shows an interface region 36 between conductors 18 of an armature coil winding 14 and a connection terminal 26 associated with a printed circuit board 20.

As shown, the conductors 18 extend toward the printed circuit board 20 and are received by the connection terminal 26. The connection terminal 26 is configured to engage the conductors 18 to establish electrical contact between the conductors 18 and conductive portions 24 of the printed circuit board 20. Each conductor 18 includes an insulating layer (not distinctly shown) surrounding a conductive core 30.

The foregoing FIGS. 1 through 4 illustrate representative prior art armature winding arrangements 14 and armature interconnection terminal 38, including printed circuit board interfaces 20 and terminal-based connections 26 used to electrically couple armature coil windings 14 to external circuitry. As discussed above, these approaches provide limited mechanical control over multiple conductors and are particularly ill-suited for bifilar windings intended to be joined at a single electrical node because of insufficient connection between the interconnection terminal 38 and the conductors 18. The following description introduces printed circuit board structures and wire capture geometries that address these limitations by mechanically positioning and retaining two winding wires on a common solder pad during soldering.

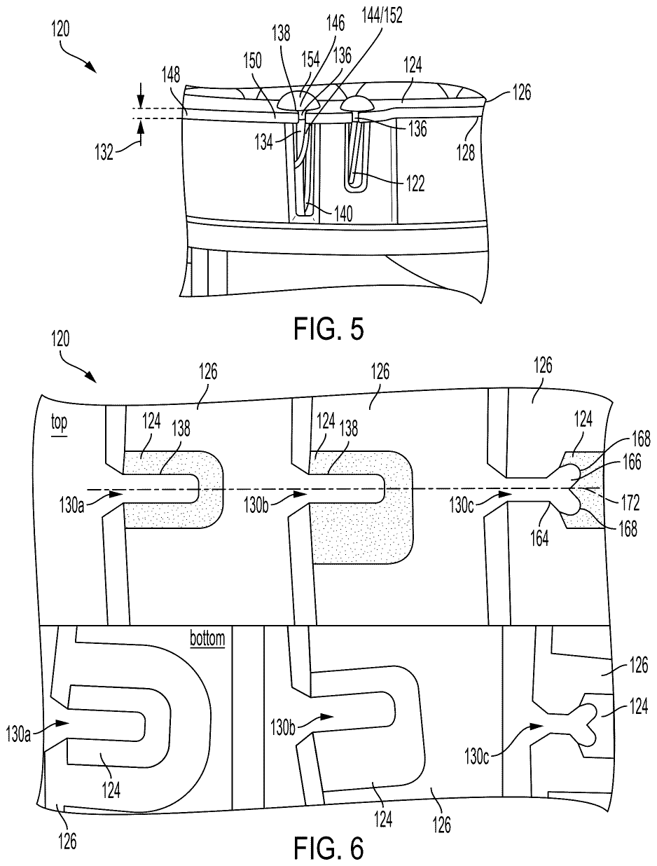

Referring now to FIG. 5, a printed circuit board 120 is illustrated in cross-section in which one or more winding wires 122 are routed through the printed circuit board 120 toward a solder pad 124 formed on a first surface 126 of the printed circuit board 120. The printed circuit board 120 includes the first surface 126 and an opposing surface 128, and one or more slots 130 (see FIGS. 6-12) extending through a thickness 132 of the printed circuit board 120 between the opposing surface 128 and the first surface 126. Each slot 130 defines a passage through which a corresponding wire 122 is routed from the opposing surface 128 to the first surface 126 adjacent the solder pad 124.

Each slot 130 includes a slot opening 134 at the opposing surface 128, a slot channel 136 extending through the thickness 132 of the printed circuit board 120, and a slot exit 138 opening at the first surface 126. The slot opening 134 may include chamfered surfaces or flared portions configured to guide insertion of the wire 122 into the slot channel 136 and to reduce contact between wire insulation 140 and edges of the printed circuit board 120 during insertion.

The slot channel 136 extends through the thickness 132 of the printed circuit board 120 and is configured to guide the wire 122 as the wire 122 passes between the opposing surface 128 and the first surface 126. The slot channel 136 has a width that varies and is selected to receive the wire 122 with sufficient clearance to permit insertion while limiting excessive lateral displacement of the wire 122 within the board thickness 132.

The slot exit 138 opens adjacent the solder pad 124 formed on the first surface 126 of the printed circuit board 120. Each wire 122 includes an insulated portion 140 that remains within or proximate to the slot channel 136 and an exposed conductor portion 144 that extends beyond the slot exit 138 toward the solder pad 124. The exposed conductor portion 144 is oriented toward the solder pad 124 such that the exposed conductor portion 144 may be soldered to a solderable surface 146 of the solder pad 124.

The solder pad 124 is formed from a conductive copper layer 148 of the printed circuit board 120 and is exposed through a solder mask opening 150. The solder pad 124 is electrically connected to one or more circuit traces 152 and defines an electrical node 154 configured to receive one or more wires 122. The solder pad 124 may be sized to accommodate soldering of multiple exposed conductor portions 144, such as in applications involving bifilar windings.

The solder pad 124 may include linear edge portion, curved boundary portions, or combinations thereof, depending on a selected pad geometry (not distinctly shown). In some embodiments, the solder pad 124 may be elongated in a direction transverse to the slots 130 to increase available solderable area. In other embodiments, the solder pad 124 may include solder mask-defined boundaries configured to limit solder spread during soldering.

After exiting the slot exits 138, the wires 122 extend along the first surface 126 of the printed circuit board 120 toward the solder pad 124. Prior to soldering, the exposed conductor portions 144 may be susceptible to movement relative to the first surface 126 of the printed circuit board 120. Such movement may include lifting away from the solder pad 124, lateral shifting across the solderable surface 146, or rotation relative to a length of the wire 122, depending on wire flexibility, exposed length, and slot geometry.

The wires 122 may have been bent during routing from an armature and through the slots 130 and may retain elastic restoring forces associated with such bending. These restoring forces may influence the position of the exposed conductor portions 144 after exit from the slots 130 and prior to soldering.

Referring now to FIG. 6, a different printed circuit board interface geometry is illustrated with the slots 130 formed adjacent a solder pad 124 on a surface 126 of a printed circuit board 120. An upper row of FIG. 6 represents CAD views. A bottom row of FIG. 6 represents actual prototype versions of the corresponding top row. The illustrated configurations depict alternative slot and terminal-region shapes formed in the printed circuit board 120 prior to placement of winding wires and prior to solder application.

FIG. 6 illustrates representative printed circuit board configurations in which slots 130a, 130b are formed in the printed circuit board 120 to route individual winding wires toward the solder pad 124, without providing a dedicated wire capture or wedging structure adjacent the solder pad 124 and therefore do not inherently establish a defined positional relationship for multiple conductors intended to be soldered to a common pad. In these configurations, each slot 130a, 130b extends through a thickness of the printed circuit board 120 and terminates in an exit 138 adjacent the solder pad 124.

FIG. 6 also illustrates a printed circuit board configuration including a slot 130c with a wire-receiving terminal region 164 formed adjacent the solder pad 124. The terminal region 164 includes a posterior wedge portion 166 defined by boundary surfaces 168 positioned substantially symmetrically about a longitudinal centerline 172 of the terminal region 164. The posterior wedge portion 166 is shaped to receive two wires in a closely spaced arrangement and to provide mechanical guidance toward the solder pad 124 when wires are subsequently introduced.

FIG. 6 illustrates interface geometries 130a, 130b lacking a dedicated wire capture structure adjacent the solder pad 124, while slot 130c illustrates a symmetric posterior wedge geometry 164 formed in the printed circuit board 120 prior to wire insertion and soldering. As described in greater detail with reference to subsequent figures, later embodiments introduce asymmetric wire capture geometries that actively constrain, seat, and retain two wires during soldering, thereby improving positional stability and solder joint consistency.

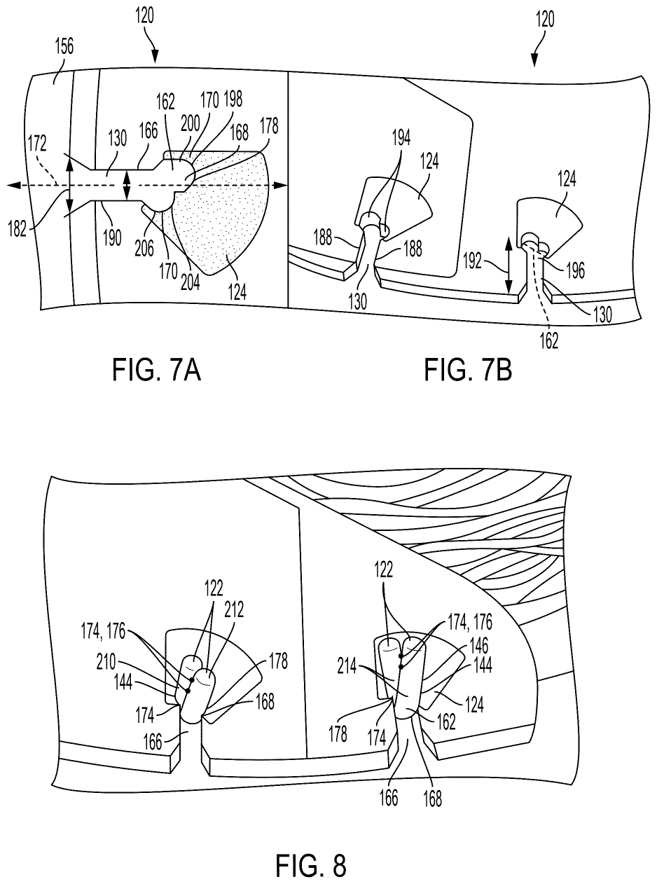

Referring now to FIGS. 7A and 7B, a printed circuit board assembly 120 is illustrated including a wire capture area 162 formed in a printed circuit board 120 adjacent a solder pad 124. FIGS. 7A and 7B depict the same wire capture geometry, with FIG. 7A illustrating a top plan view of a single slot 130 and FIG. 7B illustrating a top perspective view of the printed circuit board 120 including two slots 130 displaced along the printed circuit board 120.

The figures illustrate a schematic depiction of the printed circuit board 120 showing a geometry of the wire capture area 162 formed as a slot 130 in the printed circuit board 120. The wire capture area 162 includes an opening 156, a uniform channel 166 extending inward from the opening 156, and a posterior wedge portion 168 positioned at a terminal end 178 of the uniform channel 166 adjacent the solder pad 124. The opening 156, the uniform channel 166, and the posterior wedge portion 168 together define a continuous wire-receiving path formed in the printed circuit board 120.

The opening 156 shown has a width 182 greater than a combined width of two wires (not distinctly shown) arranged side-by-side, thereby permitting two wires to be introduced into the wire capture area 162 without precise lateral alignment at the entry point 156. The opening 156 transitions into the uniform channel 166, which has opposing side walls 188 defining a substantially constant channel width 190 along a length 192 of the channel 166.

The uniform channel 166 is configured to receive two wires in a generally side-by-side orientation while limiting excessive lateral separation and restricting relative vertical displacement between the wires as the wires advance toward the posterior wedge portion 168.

The posterior wedge portion 168 is laterally expanded relative to the uniform channel 166 and is asymmetric about a longitudinal centerline 172 of the uniform channel 166. The posterior wedge portion 168 includes curved boundary surfaces 170 defining adjacent wire-receiving regions 194 positioned with a lateral offset 196 relative to one another. As illustrated in FIG. 7A, the asymmetric geometry causes a first wire (not distinctly shown) to be urged toward and into contact with a portion 198 of the solder pad 124 along one side 200 of the posterior wedge portion 168. A second wire, in turn, is urged toward a different portion 204 of the solder pad 124 along an opposite side 206 of the posterior wedge portion 168.

In this manner, the solder pad 124 and the posterior wedge portion 168 cooperate to establish alternating contact relationships in which each wire is laterally constrained by both the other wire and adjacent geometry of the printed circuit board 120. In other words, two wire nestled snugly in region 194 can not easily move back into channel 166.

The solder pad 124 is positioned adjacent the posterior wedge portion 168 such that the solder pad 124 extends beneath at least a portion of the posterior wedge portion 168. FIG. 7A thus illustrates a laterally offset relationship between the two wires 122 created by the asymmetric geometry of the posterior wedge portion 168 in combination with a shape of the solder pad 124 prior to soldering.

As illustrated in FIGS. 7A and 7B, the wire capture area 162 is formed directly in the printed circuit board 120 and is positioned to guide two wires 122 toward the solder pad 124 while establishing a laterally offset and mechanically constrained relationship between the wires 122 prior to soldering. Interaction between the wires 122 and the wire capture area 162 during seating and soldering is described in greater detail with reference to subsequent figures.

Referring now to FIG. 8, a printed circuit board assembly 120 is illustrated in a condition following application of solder 210, in which two wires 122 of a bifilar winding 16 received within the wire capture area 162 adjacent the solder pad 124 are electrically connected to the solder pad 124 by solder joints 212.

FIG. 8 shows the two wires 122 extending from the uniform channel 166 into the posterior wedge portion 168 formed in the printed circuit board 120 as shown in FIGS. 7A and 7B. Each wire 122 includes an exposed conductor portion 144 positioned on the solder pad 124 and bonded thereto by solder 210 that has flowed and subsequently solidified. The uniform channel 166 guides the two wires 122 into a generally side-by-side orientation as the wires 122 advance toward the posterior wedge portion 168.

The posterior wedge portion 168 is positioned at the terminal end 178 of the uniform channel 166 adjacent the solder pad 124 and includes curved boundary surfaces (not distinctly shown) shaped to receive the two wires 122 therein. As illustrated in FIG. 8, the geometry of the posterior wedge portion 168 maintains the two wires 122 in laterally offset seating positions relative to one another as the solder solidifies, with each wire 122 remaining in engagement with the curved boundary surfaces.

Each wire 122 engages the posterior wedge portion 168 at one or more wire-to-slot contact regions 174 defined by the curved boundary surfaces 170. The contact regions 174 restrict lateral movement of the wires 122 relative to one another and limit upward movement of the wires 122 away from the printed circuit board 120 during and after soldering. The uniform channel 166 further constrains relative movement of the wires 122 as the wires 122 transition into the posterior wedge portion 168.

The solder pad 124 is positioned beneath and adjacent to the posterior wedge portion 168 such that the exposed conductor portions 144 of both wires 122 are in contact with the solderable surface 146 of the solder pad 124 during solder flow. FIG. 8 illustrates solder joints 212 formed at the solder pad 124, with solder fillets 214 extending around the exposed conductor portions 144 of the wires 122.

The configuration shown in FIG. 8 illustrates that the wire capture area 162 maintains the two wires 122 in a defined positional relationship relative to the solder pad 124 during solder flow and solder solidification. The geometry of the uniform channel 166 and the posterior wedge portion 168 cooperates to resist displacement of the wires 122 during soldering and to preserve the relative positioning established prior to solder application.

Following solder solidification, the posterior wedge portion 168 remains engaged with the wires 122 and continues to provide mechanical retention adjacent the solder pad 124. Forces transmitted along the wires 122 may be distributed between the solder joints 212 and the contact regions 174, 176 between the wires 122 and the wire capture area 162. In other words, even after soldering, the arrangement of the wires 122 in the wedge portion 168 continues to provide strain relief.

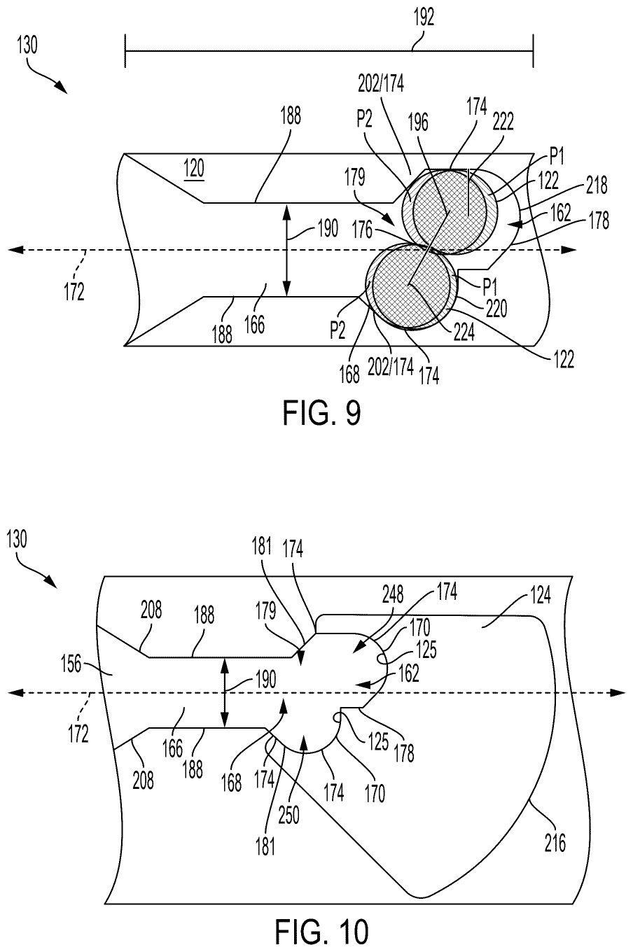

Referring now to FIG. 9, an enlarged view of a wire receiving slot 130 formed in a printed circuit board 120 is illustrated, showing a detailed geometry of the slot 130 configured to receive two winding wires 122 and to mechanically engage and wedge the wires 122 relative to one another and relative to the printed circuit board 120. FIG. 9 illustrates exemplary ranges of different seated positional configurations of the wires 122 within the slot 130, identified herein as a first seated position P1 and a second seated position P2, which are distinguished in the figure by different cross-hatching patterns applied to the wires 122.

The slot 130 extends inward from the surface 126 of the printed circuit board 120 and includes the uniform channel 166 and the posterior wedge portion 168 positioned at the terminal end 178 of the uniform channel 166. The uniform channel 166 includes opposing side walls 188 defining a substantially constant channel width 190 along the channel length 192. The channel width 190 is greater than a diameter of each of the two wires 122 individually and smaller than a combined width of the two wires 122, such that both wires 122 may pass through the uniform channel 166 simultaneously while remaining adjacent to one another in a generally single file orientation.

At the terminal end 178 of the uniform channel 166, the slot 130 transitions into the posterior wedge portion 168. The posterior wedge portion 168 is laterally expanded relative to the uniform channel 166 and is asymmetric about the longitudinal centerline 172 of the uniform channel 166. The posterior wedge portion 168 includes a first curved boundary surface 218 and a second curved boundary surface 220 that are laterally and axially offset relative to one another.

The first curved boundary surface 218 defines a generally elongated semi-circular profile having a radius 222 corresponding approximately to the radius of one of the wires 122. The second curved boundary surface 220 defines a semi-circular profile having a radius 224 corresponding approximately to the radius of the other wire 122. Again, the elongated semi-circular profile is shifted relative to the semi-circular profile such that the first curved boundary surface 218 and the second curved boundary surface 220 do not share a common center point.

In the first, right-biased, seated position P1 illustrated in FIG. 9 by a first cross-hatching pattern, when the two wires 122 advance from the uniform channel 166 into the posterior wedge portion 168, a first wire 122 is received along the first curved boundary surface 218 and seats deeper within the posterior wedge portion 168 relative to a second wire 122. The second wire 122 is received along the second curved boundary surface 220 and is urged laterally toward the first wire 122, bringing the two wires 122 into contact with one another at a contact region 176 while each wire 122 simultaneously engages a respective curved boundary surface 218, 220.

In the second, left-most, seated position P2 illustrated in FIG. 9 by a second, different cross-hatching pattern, the relative positions of the two wires 122 within the posterior wedge portion 168 are shifted, such that the wires 122 wedge against the bank surfaces 202 and wire-to-wire contact region 176.

In each of the first seated position P1 and the second seated position P2 shown in FIG. 9, each wire 122 contacts the slot 130 at multiple wire-to-slot contact regions 174, and the two wires 122 contact one another at a wire-to-wire contact region 176. Together, the wire-to-slot contact regions 174 and the wire-to-wire contact region 176 restrict lateral separation of the wires 122, limit upward movement of the wires 122 away from the printed circuit board 120, and inhibit relative rotation of the wires 122 within the slot 130.

The asymmetric geometry of the posterior wedge portion 168 thus permits many alternative seated positional configurations P1, P2 of the wires 122 while maintaining wedging engagement between the wires 122, the first curved boundary surface 218, the second curved boundary surface 220, wire-to-slot contact regions 174, and bank surfaces 202. In both seated positions P1 and P2, elastic restoring forces of the wires 122 contribute to maintaining the wires 122 in wedged engagement at the wire-to-slot contact regions 174 and the wire-to-wire contact region 176. In short, while the upper wire 122 is in boundary surface 220, the lower wire 122 at least partially blocks the channel 166 and abuts the upper wire 120 so that neither wire can escape the respective boundary surface 218, 220. Each wire 122 effectively pushes the other wire 122 into the boundary surfaces 218, 220 to have a wedging effect.

The slot 130 is dimensioned based on sizes of the wires 122 being received. In the embodiment illustrated, the two wires 122 have approximately equal diameters, and the first curved boundary surface 218 and the second curved boundary surface 220 have curvature radii 222, 224 selected accordingly. The relative channel width 190, lateral offset 196 between the curved boundary surfaces 218, 220, and curvature radii 222, 224 of the posterior wedge portion 168 are proportioned such that the wires 122 are mechanically constrained and wedged together, such as, in the first seated position P1 or the second seated position P2, when simultaneously present in the slot 130.

Still referring to FIG. 9, the wire capture area 162 has a closed or terminal end 178 opposing an open end 179, the open end 179 having surfaces 181 configured to retain ends of the wires 122 that are stripped and bent on to the solder pad 124 adjacent the closed end so that bent portions of the wires 122 flex between the surfaces 181 and the solder pad 124. The ends of the wires 122 may first be wedged in the wire capture area 162, then bent or pressed toward the solder pad 124. The wires 122 may be trimmed to a final length with the resilient nature of the wire being utilized to press the ends against the solder pad as the wires extend from the surfaces 181.

Referring now to FIG. 10, a printed circuit board assembly 120 is illustrated showing the geometry of a wire receiving slot 130 corresponding to that shown in FIG. 9, with the wires removed for clarity and with a solder pad 124 shown. FIG. 10 illustrates a first seating area 248 and a second seating area 250 of two wires relative to a wire capture area 162 and the solder pad 124, thereby depicting the alternative seating configurations of the wires within the wire capture area 162 prior to soldering.

Adjacent the solder pad 124, the printed circuit board 120 defines the wire capture area 162, which includes an opening 156 forming a wire entrance, a uniform channel 166 extending inward from the opening 156, and a posterior asymmetric wedge portion 168 positioned between the uniform channel 166 and the solder pad 124.

The opening 156 is configured to receive two wires and transitions into the uniform channel 166. The uniform channel 166 includes opposing side walls 188 defining a substantially constant channel width 190 configured to guide two wires in a generally single file orientation while limiting separation. As illustrated, the uniform channel 166 further defines opposing guide surfaces 208 along which the wires are guided as the wires advance inward from the opening 156 toward the posterior asymmetric wedge portion 168.

At an inward end of the uniform channel 166, the wire capture area 162 transitions into the posterior asymmetric wedge portion 168. The posterior asymmetric wedge portion 168 includes a first elongated semi-circular opening and a second, laterally shifted semi-circular opening, defining the first seated area 248 and the second seated area 250. The first seated area 248 and the second seated area 250 are asymmetric about a longitudinal centerline 172 of the uniform channel 166 and together define a wedging region configured to receive two wires in laterally offset positions.

As mentioned prior, in the first seated area 248, a first wire is received seats deeper within the posterior asymmetric wedge portion 168, while a second wire is received in the second seated area 250. The two wires are laterally offset and positioned in wedging engagement with one another and with the posterior asymmetric wedge portion 168.

The wedge portion 168 is positioned immediately adjacent the solder pad 124. As illustrated, the solder pad 124 includes an arcuate portion 216 and extends beneath and at least partially around the wedge portion 168. The solder pad 124 further defines opposing bank surfaces 125 adjacent the wedge portion 168, which are positioned to support exposed conductor portions of the wires when the wires are seated in the first seated area 248 and the second seated area 250.

As the wires advance from the uniform channel 166 into the posterior asymmetric wedge portion 168 and toward the solder pad 124, the wires are bent relative to an incoming path defined by the uniform channel 166. This bending introduces elastic restoring forces that urge the wires into continued engagement with the wire-to-slot contact regions 174 defined by the curved boundary surfaces 170, and one another, thereby maintaining the wires in their respective seated areas 248, 250.

In each of the first seating area 248 and the second seating area 250 illustrated in FIGS. 9 and 10, the geometry of the wire capture area 162 positions the exposed conductor portions of both wires directly over and in contact with the solderable surface of the solder pad 124 prior to soldering, while restricting lateral separation, upward movement away from the printed circuit board 120, and relative rotation of the wires.

Accordingly, FIG. 10 illustrates the wire capture area 162 and the solder pad 124 in isolation, showing the positional relationship of the first seated area 248 and the second seated area 250 of the wires relative to the uniform channel 166, the posterior asymmetric wedge portion 168, and the solder pad 124 prior to solder application.

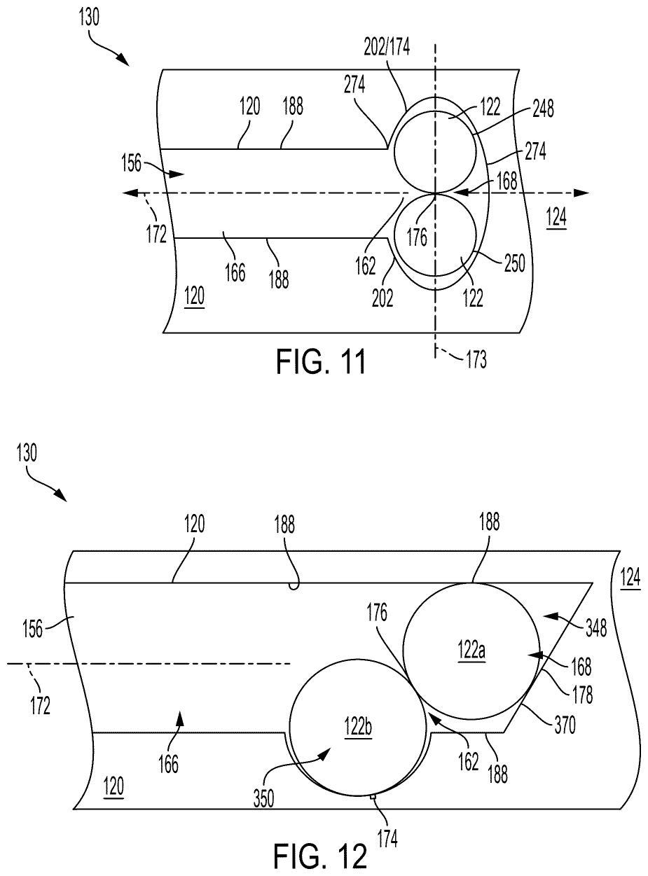

Referring now to FIG. 11, a printed circuit board assembly 120 is illustrated showing a variation of a wedge portion 168 relative to the configuration described with respect to FIG. 10. In FIG. 11, the wire capture area 162 adjacent the solder pad 124 may have some of the same general structure and function as described with respect to FIGS. 7 through 10, including an opening, a uniform channel 166, and a posterior wedge portion 168 configured to receive two wires 122 of a bifilar winding. In the embodiment of FIG. 11, the posterior wedge portion 168 is configured such that the two wires 122 are received in substantially symmetric seating areas 248, 250 relative to the longitudinal axis 172 of the uniform channel 166. As the wires 122 advance into the posterior wedge portion 168, the wires 122 are urged laterally toward one another until the two wires 122 contact one another at a wire-to-wire contact region 176. At the same time, each wire 122 is urged into contact with a respective bank surface 202 of the printed circuit board 120 at a wire-to-slot contact region 174. The combined engagement at the wire-to-wire contact region 176 and the wire-to-slot contact regions 174 mechanically restrains the two wires 122 against lateral separation, vertical lift, and relative rotation, thereby holding the bifilar winding in a stable position in the wedge portion 168 during solder application.

In the embodiment illustrated in FIG. 11, the posterior wedge portion 168 has an ovoid boundary surface 170 that is elongated along an axis 173 transverse to the longitudinal axis 172 of the uniform channel 166. The boundary surface 170 includes a relatively straight or low curvature edge region 274 at a terminal end of the uniform channel 166 that transitions into a rounded profile of increasing curvature in the transverse direction, resulting in an egg shaped geometry. When the two wires 122 are seated within the posterior wedge portion 168, exposed conductor portions (not explicitly shown) of both wires 122 extend from the wire-to-slot contact regions 174 onto the solderable surface 146 of the solder pad 124 and are supported along the locally linear portion of the perimeter 274. The symmetric seating of the wires 122 causes elastic restoring forces of the wires 122 to bias the wires into continued engagement at the wire-to-wire contact region 176 and the wire-to-slot contact regions 174 during soldering, thereby maintaining both exposed conductor portions 144 in contact with the solder pad 124 while solder is applied and solidified.

Referring now to FIG. 12, a printed circuit board assembly 120 is illustrated showing a further variation of the wire capture geometry relative to the embodiments described with respect to FIGS. 7 through 11. In the embodiment of FIG. 12, the wire capture area 162 adjacent the solder pad 124 again includes a slot 130 formed in the printed circuit board 120. The slot 130 includes an opening 156, a uniform channel 166 extending inward from the opening 156, and a closed-end wedge portion 168 positioned adjacent the solder pad 124. In this embodiment, however, the uniform channel 166 extends further toward the solder pad than in previously described configurations, and the posterior wedge portion 168 is configured to cooperate with the extended uniform channel 166 to establish vertically offset seating positions for the two wires 122.

As illustrated in FIG. 12, the uniform channel 166 includes a first channel seated area 348 configured to receive a first wire 122a and a second, lower seated area 350 configured to receive a second wire 122b. The lower seating area 350 has a substantially semi-circular cross-sectional shape that closely conforms to an exterior profile of the second wire 122b, such that the second wire 122b is cradled within the lower seated area 350 by wire-to-surface contact region 174 to be restrained against upward movement relative to the printed circuit board 120 by the first wire 122a. The first wire 122a is received above the second wire 122b in the channel seated area 348 of the uniform channel 166 and is constrained against movement along axis 172 by the second wire 122b and a terminal end 178. The upper side wall 188 of the channel 166 and the terminal end 178 limit travel transverse the axis 172, e.g., upward and downward. It is envisioned that with different size wires and capture areas, different combinations of surfaces will accomplish the same desired capturing effect.

At a terminal end 178 of the uniform channel 166, the slot 130 includes a slanted boundary endwall 370 forming part of the wedge portion 168. The slanted boundary surface endwall 370 engages the first wire 122a as the first wire 122a advances toward the solder pad 124 and urges the first wire 122a upward away from the second wire 122b so the second wire 122b can pop into the lower seating area 350. As a result, the first wire 122 is brought into contact with the second wire 122b at a wire-to-wire contact region 176, while the second wire 122b remains seated within the substantially circular lower seated position of the uniform channel 166. The combined engagement between the slanted boundary surface, the wire-to-wire contact region 176, and wire-to-slot contact regions 174 restricts relative vertical displacement, lateral separation, and rotation of the two wires 122a, 122b within the slot 130. In short, the wires 122a, 122b are captured in the wedge portion 168.

In this configuration, the extended uniform channel 166 establishes a defined vertical relationship between the two wires 122a, 122b prior to contact with the solder pad 124. Elastic restoring forces generated as the first wire 122a is fixed between the slanted boundary endwall 370 and channel wall 188 bias the first wire 122e into continued engagement with the second wire 122b, which is pushed into the capture area 350. The second wire 122b, being seated within the substantially circular lower seating area 350, resists upward and side-side displacement as well as serving as a stabilizing reference for the first wire 122a. Together, these interactions maintain both wires 122a, 122b in a mechanically locked relationship within the wire capture area 162 as the exposed conductor portions extend toward and contact the solderable surface of the solder pad 124 during soldering.

It is to be understood that the foregoing description is illustrative only and is not intended to be limiting. Various changes may be made in the function and arrangement of elements without departing from the scope of the disclosure. For example, various size and shaped capture areas can be utilized for various numbers of wires to deploy the subject technology. For example a somewhat quartrefoil shaped capture area may well capture four wires. Wires may be different sizes and shapes (e.g., square, oval, flat, etc.) with complimentarily shaped surfaces for capture. The scope of the invention is defined by the claims that follow, and all equivalents of the claims are intended to be encompassed thereby. It is also envisioned that any claim or feature disclosed herein, may be present in another embodiment in any combination.

The terminology used herein is for the purpose of describing particular embodiments only and is not intended to be limiting. As used herein, the singular forms “a,” “an,” and “the” include plural referents unless the context clearly indicates otherwise. The terms “comprising,” “including,” and “having” are intended to be open-ended and to mean “including, but not limited to.”

References to “one embodiment,” “an embodiment,” “certain embodiments,” or similar language mean that a particular feature, structure, or characteristic described in connection with that embodiment may be included in at least one embodiment, but not necessarily in all embodiments. Different features described in connection with different embodiments may be combined in any suitable manner in one or more embodiments, unless the context clearly indicates otherwise. All patents, patent applications and other references disclosed herein are hereby expressly incorporated in their entireties by reference.

Any characterization of an embodiment as “preferred” or “advantageous” is not intended to limit the scope of the claims. No feature or element described herein is essential or indispensable unless expressly stated as such. Headings are provided for convenience only and do not affect the interpretation of the specification or claims.

In the drawings, certain features may be illustrated schematically or not to scale, and the depiction of a feature in a particular figure does not imply that the feature is required in all embodiments. Reference numerals are provided for convenience and are not intended to be limiting, and like reference numerals may refer to like elements in different figures.

What is claimed is:

1. A printed circuit board assembly comprising:
a printed circuit board including a first surface defining a solder pad; and a second surface defining a wire capture area formed in the printed circuit board adjacent the solder pad,
wherein the wire capture area is configured to receive two wires of a bifilar winding and to mechanically wedge the two wires together by engagement with the second surface of the wire capture area to maintain the two wires in a fixed position relative to the solder pad during soldering.

2. The printed circuit board assembly of claim 1, wherein the wire capture area includes a wedge portion configured to compress the two wires toward one another when the two wires are received in the wire capture area.

3. The printed circuit board assembly of claim 2, wherein the wedge portion is positioned relative to the solder pad such that compression of the two wires also urges exposed conductor portions of both wires into contact with the solder pad.

4. The printed circuit board assembly of claim 1, wherein the wire capture area includes:
a uniform channel configured to receive the two wires in a single file orientation along an axis; and
a wedge portion positioned at a terminal end of the uniform channel allows aligning the two wires transverse to the axis for constraining relative movement of the two wires once inserted therein.

5. The printed circuit board assembly of claim 4, wherein the uniform channel has a width greater than a diameter of each of the two wires individually and smaller than a sum of diameters of the two wires, such that the uniform channel prevents one wire from passing above or below the other wire.

6. The printed circuit board assembly of claim 4, wherein the wire capture area further includes an opening leading into the uniform channel, the opening having a funnel-shape and being configured to permit insertion of the two wires without precise lateral alignment while transitioning the two wires into a constrained side-by-side orientation within the uniform channel.

7. The printed circuit board assembly of claim 4, wherein the wedge portion includes curved boundary surfaces configured to establish multiple simultaneous contact regions between the two wires and the printed circuit board when the two wires are seated.

8. The printed circuit board assembly of claim 7, wherein the curved boundary surfaces are arranged asymmetrically such that one of the two wires is urged into a laterally offset position relative to the other wire during seating in the wedge portion.

9. The printed circuit board assembly of claim 8, wherein the wedge portion is configured such that elastic restoring forces of the two wires increase a wedging force between the two wires after insertion into the wedge portion.

10. A printed circuit board assembly comprising:
a printed circuit board defining a solder pad configured as a single electrical node; and
a slot formed in the printed circuit board adjacent the solder pad;
wherein:
the slot includes a uniform channel and a wedge portion,
the uniform channel is configured to receive two wires of a bifilar winding in a single file orientation, and
the wedge portion is configured to compress the two wires toward one another such that, when seated therein, the wedge portion and resulting elastic restoring forces of the two wires cooperate to retain the two wires in contact with the solder pad.

11. The printed circuit board assembly of claim 10, wherein the uniform channel has a width greater than a diameter of each of the two wires individually and smaller than a sum of diameters of the two wires, thereby preventing one wire from passing by the other wire.

12. A printed circuit board assembly comprising:
a printed circuit board including a solder pad;
a wire capture area formed in the printed circuit board adjacent the solder pad; and
a wire path connected to the wire capture area for guiding wired therein,
wherein the wire capture area is configured to fix at least two wires therein and the wire path that mechanically constrains movement of the two wires in at least relative vertical displacement as the two wires are advanced toward the solder pad, such that insertion of the two wires into the wire capture area generates contact forces between the two wires and the printed circuit board that maintain exposed conductor portions of both wires in contact with the solder pad during soldering.

13. The printed circuit board assembly of claim 12, wherein the wire capture area has a closed end opposing an open end, the open end having surfaces configured to retain ends of the at least two wires that are stripped and bent on to the solder pad adjacent the closed end so that bent portions flex between the surfaces and the solder pad.

14. The printed circuit board assembly of claim 12, wherein the guided wire path includes a uniform channel that receives the at least two wires in a pre-determined orientation and prevents one of the at least two wires from passing above or below another of the at least two wires prior to contact with the solder pad.

15. The printed circuit board assembly of claim 12, wherein the wire capture area has at least two arcuate surfaces complimentarily shaped to the at least two wires and includes a neck region adjacent the guide wire path so that one of the at least two wires at least partially blocks the guide wire path and wedges against another of the at least two wires when in the wire capture area.
